(19) United States
(12) Patent Application Publication
(10) Pub. No.: US 2019/0191133 A1
(43) Pub. Date: Jun. 20, 2019

(54) LASER LED HYBRID LIGHT SOURCE FOR PROJECTION DISPLAY

(71) Applicant: Michael OSTROW, East Meadow, NY (US)

(72) Inventor: Michael Ostrow, East Meadow, NY (US)

(21) Appl. No.: 16/327,155

(22) PCT Filed: Aug. 7, 2017
(86) PCT No.: PCT/US2017/045670

§ 371 Date: Feb. 21, 2019

Related U.S. Application Data
(60) Provisional application No. 62/377,798, filed on Aug. 22, 2016.

(51) Int. Cl. H04N 9/31; G03B 21/16; G03B 21/20; H01S 5/323

(52) U.S. Cl. CPC H04N 9/3161; G03B 21/16; H01S 5/32341; H04N 9/3111; H04N 9/3158; G03B 21/204

(57) ABSTRACT

The present invention is a light source for a projection display. The light sources has a heat sink; a phosphor composition provided on the heat sink, wherein the phosphor composition is a phosphor powder, a ceramic phosphor or a liquid phosphor; one or more lasers directed at the phosphor composition; an electronic circuit connected to the one or more lasers to regulate power output to the one or more lasers; and a power source connected to the electronic circuit, wherein when the one or more lasers are activated exciting the phosphor composition the light emitted from the phosphor composition is the light source for the projection display.

### FURTHER ADDITIONAL MATERIALS

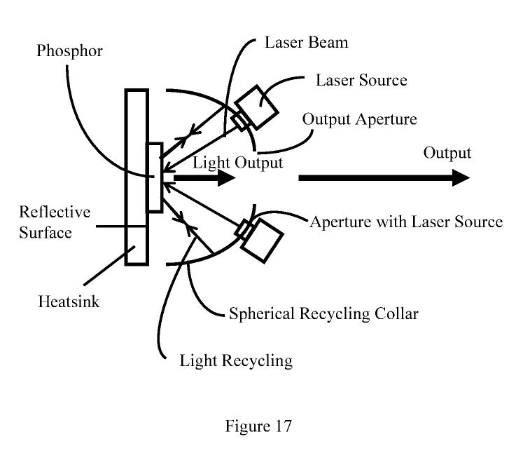

FIGS. 17 to 23

Phosphor materials for laser excitation can be divided generally into 3 categories depending on their power handling capabilities.

1—Phosphor powder—composed of phosphor powder bound together by organic materials like glue, epoxy, etc, such that a thin layer can be form by putting the material on top of a substrate, e.g. glass, metal, etc. The limitation is heat sinking of the phosphor and the burning of the glue by the excitation laser.

2—Ceramic phosphor—composed of phosphor powder bound together by inorganic materials like glass and is usually in solid form and stands alone as a thin sheet of ceramic phosphor. Since there is no “glue”, it can stand much higher temperature at higher laser power.

3—Liquid phosphor—composed of a cell with phosphor powder suspended in liquid. The phosphor can be made flowing so that the heat can be removed quickly increasing the power handling capacity of the system.

The following disclosures describe phosphor on top of a heatsink, but the configurations can be applied to systems including the 3 types of phosphor described above.

FIG. 17 shows a laser excited phosphor system with a layer of phosphor on top of a heatsink. The layer of phosphor can be any of the 3 configuration described above. A spherical recycling collar is placed such that the center of curvature is substantially at the location of the phosphor such that light emitted by the phosphor will be reflected back to itself. Part of the light emitted by the phosphor exits the aperture of the recycling collar forming the output of the system. The portion of the light not exiting the aperture will be reflected back to the phosphor by the recycling collar. Part of the light hitting the phosphor will be re-emitted and exit the aperture as output of the system and part of the light will be reflected back to the phosphor again by the recycling collar. The light emitted by the phosphor is from the excitation laser source placed around the recycling collar through a smaller aperture such that the laser beam can enter without loss.

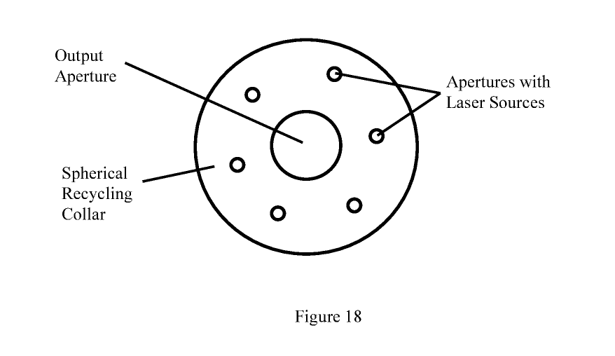

An example of the laser source configuration is shown in FIG. 18. In this particular example, 6 laser sources are used and they are placed uniformly around the recycling collar. The number of laser can be adjusted to provide the needed total laser power. For high efficiency operation, the aperture for the laser beam is made small relative to the size of the recycling collar such that minimum amount of surface area for recycling is removed.

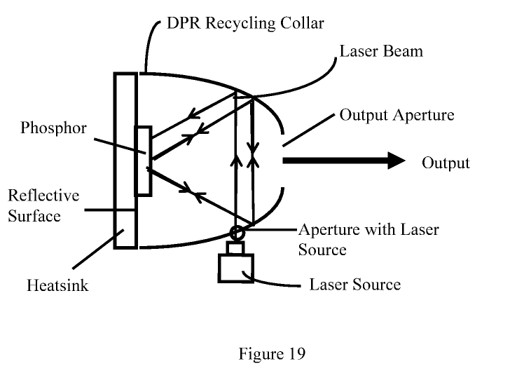

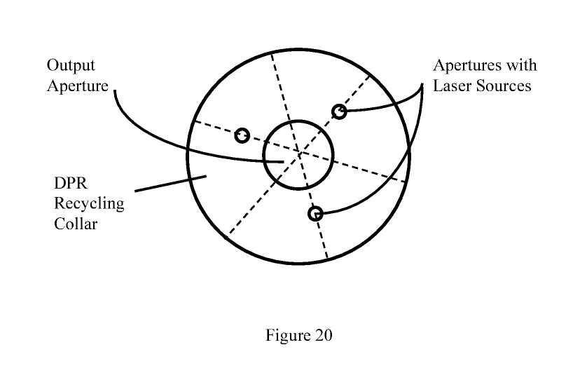

FIG. 19 shows another configuration in which the recycling collar is parabolic such the two reflections are required. The first reflection collimates the beam and the second reflector focuses the beam back to the phosphor. In this case, the excitation laser source will have the beam entering the aperture and reflected by the other side of the parabolic reflector and focused onto the phosphor. As a result, the configuration of the laser sources around the recycling collar has to be adjusted as shown in FIG. 20 such that the laser sources are not directly opposite to each other.

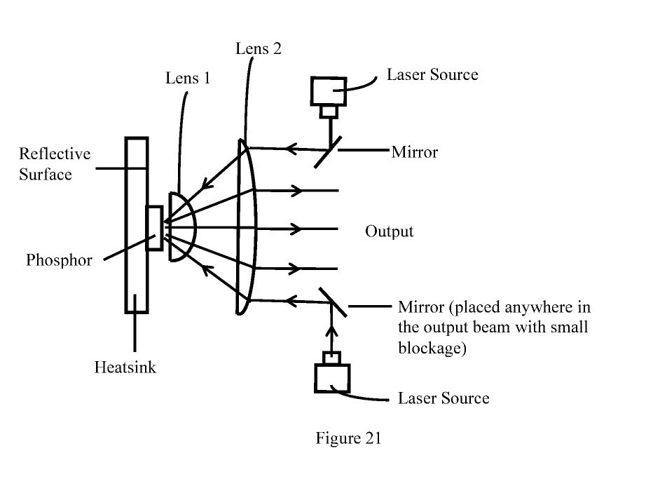

FIG. 21 shows another configuration using laser sources to excite the phosphor. In this case, multiple lenses are used to collect and collimate the light emitted by the phosphor, e.g., lens1 and lens2 as shown. The laser source is place outside the output of the side such that the laser beam is reflected by a small mirror towards the phosphor as shown. Since the mirror is small and matches the size of the laser beam, the amount of output blockage is minimal.

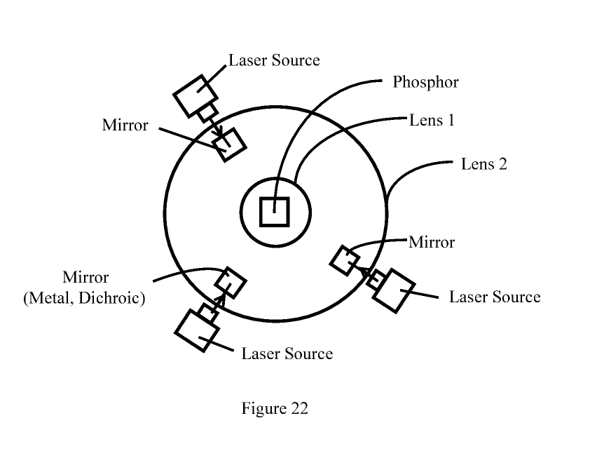

FIG. 22 shows an example of such configuration with 3 laser sources and 3 small mirrors around the edge of the output beam. Depending on the exact wavelength under consideration, the mirror can be made with dichroic coatings such that it reflects the laser beam and transmit the outputs emitted by the phosphor, reducing the blocking loss of the system.

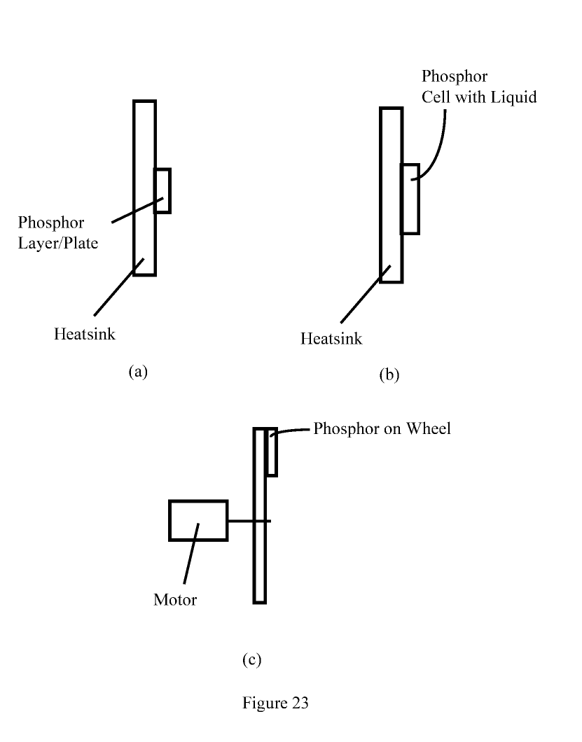

FIG. 23 shows various configurations of the phosphor with (a) phosphor powder/glue or ceramic phosphor on top of a heatsink, (b) phosphor suspension in liquid, and (c) phosphor on a rotating wheel such that the surface area is increase, reducing the effective areas, and increasing the total power handling capacity.

### ADDITIONAL MATERIALS

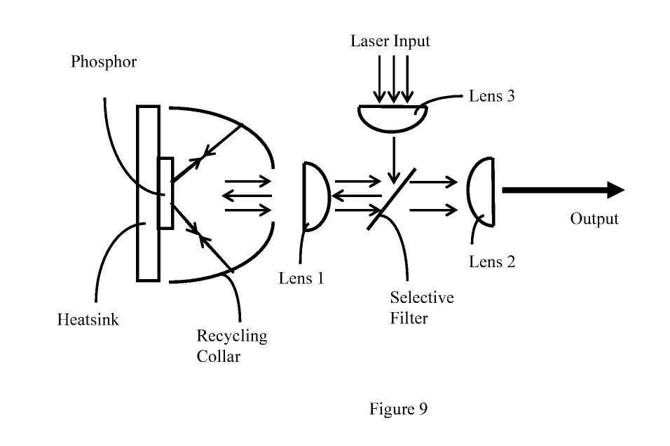

FIGS. 9 to 16

FIG. 9 shows an embodiment of a light source driven by laser input. The laser can be UV or blue laser made with semi-conductor materials, solid state, or other laser materials, including gas lasers. The laser input is reflected toward the phosphor, which absorbs the laser radiation and emission light of various colors depending on the materials used. For example, white, red, green, blue, or other colors can be generated. The phosphor material is placed on top of a heatsink such that the temperature of the phosphor remains low for efficient operations. One or more types of phosphor materials with different colors can be used either as a mixture or spatially placed on the heatsink such that the desired color can be obtained. The heatsink is also made reflective such that the laser light and the emitted light from the phosphor are all directed towards the direction of the output. The output from the phosphor is usually lambertian and contains a lot of high angle emission. In this embodiment, the high angle emissions are reflected back to the phosphor with the reflective collar. The collar can spherical in shape in forming an imaging device, images the phosphor back into itself. Through the aperture of the recycling collar, the output is collimated by Lens 1. The output emission is then transmitted through the selective filter, which transmits the light emitted by the phosphor and reflects the light of the laser. The output parallel beam can also be focused to a small spot using the optional focusing lens 2.

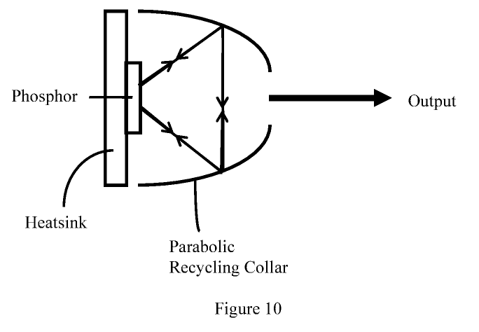

FIG. 10 shows another configuration of the recycling collar with parabolic shape such that the light reflector from the surface will be parallel to the heatsink and reflected by the collar again back to the phosphor. In this configuration, the phosphor is place at the focus of the parabolic surface.

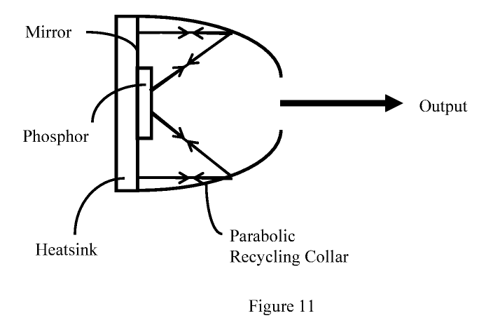

FIG. 11 shows another configuration of the recycling collar with parabolic shape. In this case, the phosphor is placed at the focus of the parabolic reflector such that the light is reflected back toward the heatsink and perpendicular to the heatsink. A reflector is place parallel or on top of the heatsink such that the parallel beam is reflected towards the parabolic reflector and focused back to the phosphor for recycling.

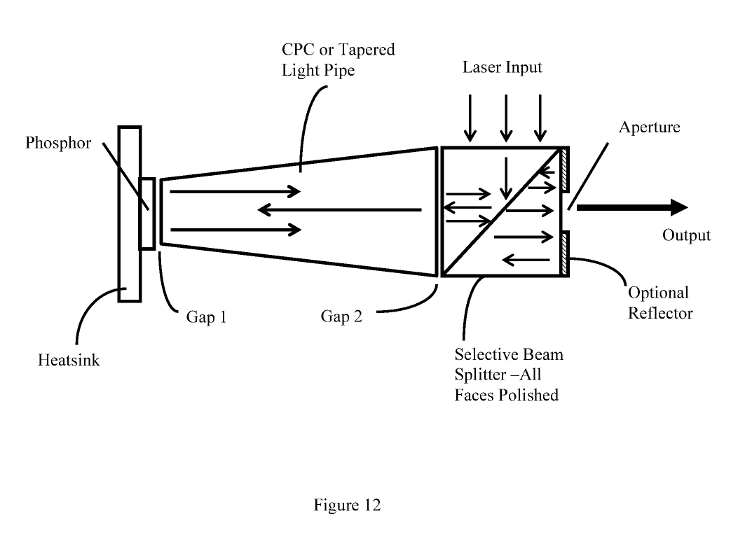

FIG. 12 shows an embodiment using a tapered light pipe or CPC. The laser light is incidence at the selective beam splitter such that the laser beam is reflected towards the tapered light pipe and onto the phosphor. The emitted light from the phosphor is coupled into the tapered light pipe, into the selective beam splitter such that the light is transmitted through towards the output. The selective beam splitter has all six side faces polished such that it acts as waveguides with total internal reflection occurs at the triangular faces of the prisms forming the beam splitter. The dimensions of the output face of the tapered light pipe are substantially the same as the input face of the beam splitter. The output face of the beam splitter can be partially covered with reflective surface such that part of the output can be coupled back to the phosphor for recycling. An optional reflective polarizer, not shown, can be place at this output aperture such that unused polarization can be recycled also.

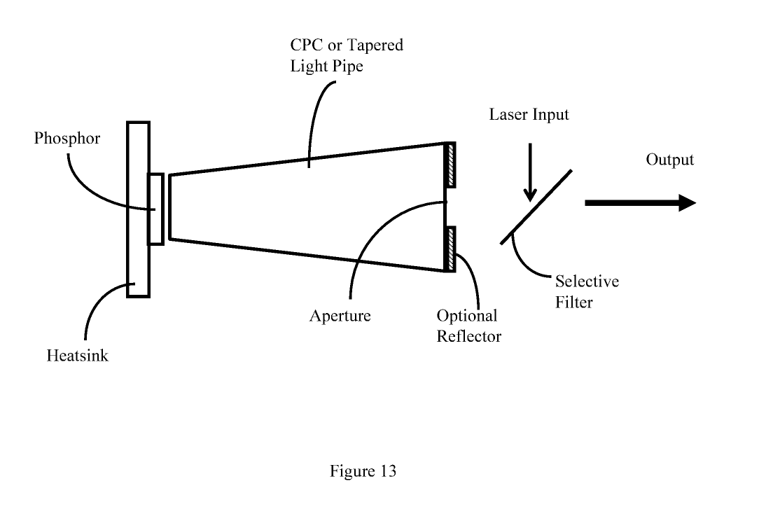

FIG. 13 shows another embodiment in which the selective beam splitter is replaced by a selective filter plate such that the laser light is reflective towards the phosphor and the output light from the phosphor is transmitted through this selective filter. The output face of the tapered light pipe can also be coated partially with reflective coating, leaving a aperture for output.

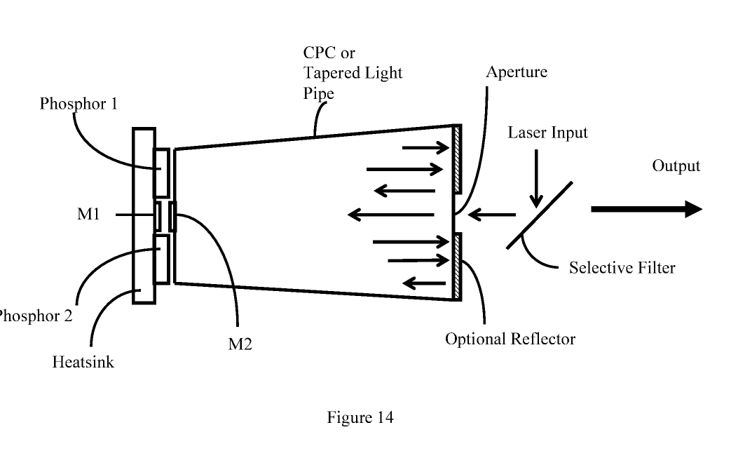

FIG. 14 shows another embodiment in which more than one phosphor emitting areas can be accommodated. In this case, the areas without the phosphor can be coated with a reflective surface M1 such that recycled light will be reflected back towards the output outside the phosphor areas. In another configuration, instead of coating the heatsink reflective, the input of the light pipe can be coated reflective being shown as M2.

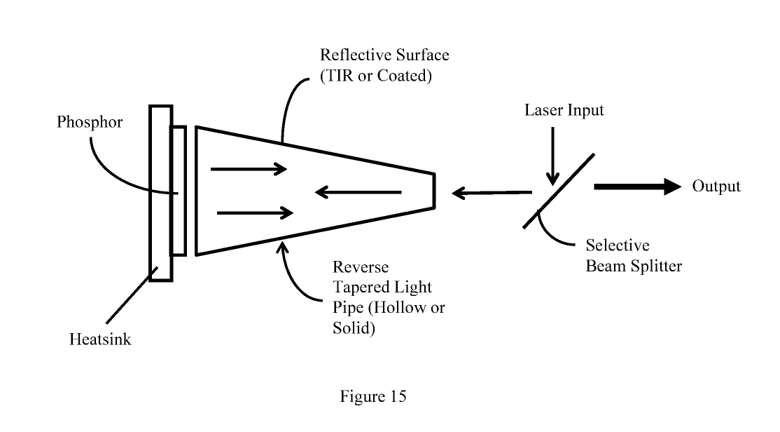

FIG. 15 shows another embodiment in which the light pipe is reverse tapered such that high angle emission from the phosphor will be reflected back to the phosphor for recycling. In the case of a solid reverse tapered light pipe, the outside surface has to be coated with reflective coating.

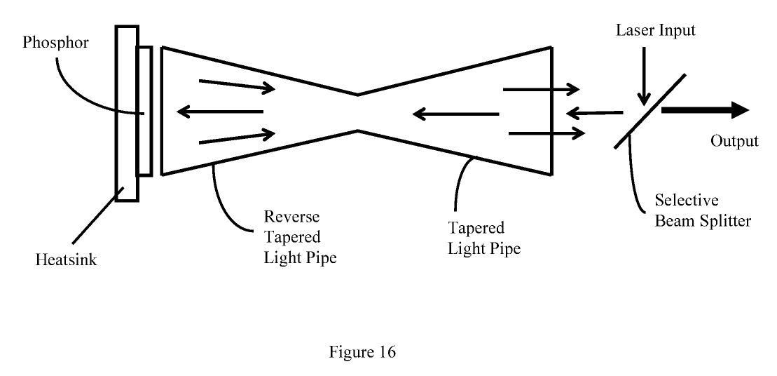

FIG. 16 shows an embodiment with the addition of a tapered light pipe such that the output face dimension and angle of light output can be adjusted.

Although FIGS. 15 and 16 shows the embodiments with tapered light pipe, solid or hollow, they can also be made using CPC's, solid or hollow. Again, if solid CPC is used, the outside has to be coated with a reflective coating.

A white LED is used for projection display with the advantage that it is simpler than combining red, green, and blue LEDs together, and will lower the cost of the system.

The output of the projector is limited by the brightness of the LED. Recycling of unused LED light back to the LED itself increases the output brightness, and thus, the output of the projector. To further increase the output, a new scheme is needed.

This invention discloses the use of a blue or UV laser to excite the phosphor of a system such that the brightness is increased.

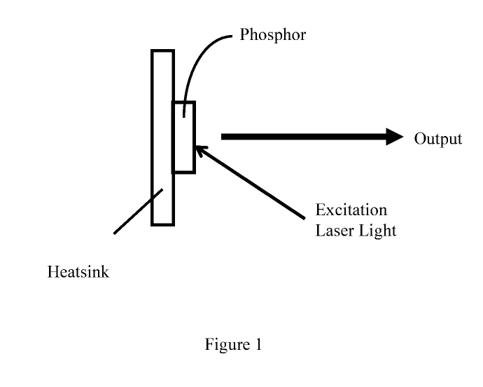

FIG. 1 shows the basics of generation of light from phosphor using a laser. Multiple lasers can be used to further increase the brightness.

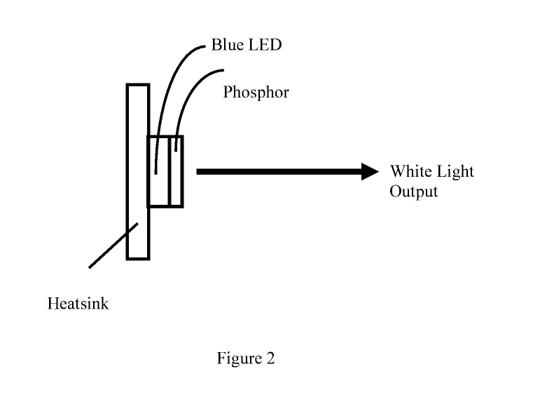

FIG. 2 shows the construction of a white LED, which includes a blue LED and a phosphor layer, excited by the blue light and generates the red and green light. The phosphor is adjusted such that the total output consists of red, green, and blue light, produce a white output.

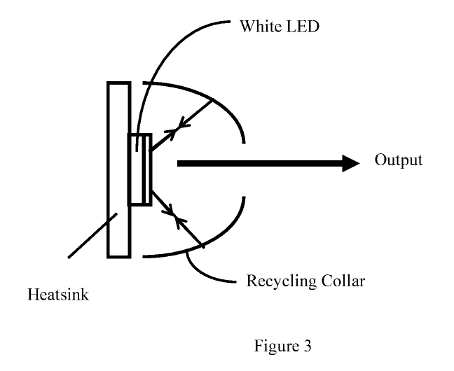

FIG. 3 shows the increase of brightness using a recycling collar, such that part of the unused output is reflected back to the LED. Part of the reflected light will be coupled to the output, increasing the brightness.

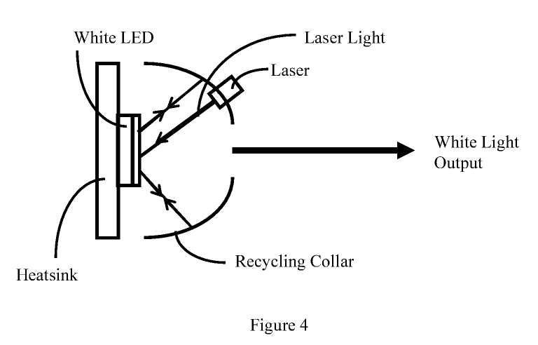

FIG. 4 shows the addition of the UV or blue laser light directed at the phosphor layer of the LED, excites the phosphor, thus produces added output to the original LED, increasing the brightness of the system. As shown in the figure, one or more lasers can be used depending on the output required, the light handling capability of the white LED, the heat sinking capacity of the LED, and the lifetime requirement of the system. The laser can be mounted onto the recycling collar. The laser can also be external to the recycling collar and the beam is directed onto the white LED through a hole in the collar.

In another embodiment, the white LED can be replaced simply by a phosphor layer coated on a heat sinking substrate. In this case, this will be a purely laser system.

In another embodiment, the recycling collar is not used for lower output, lower cost systems.

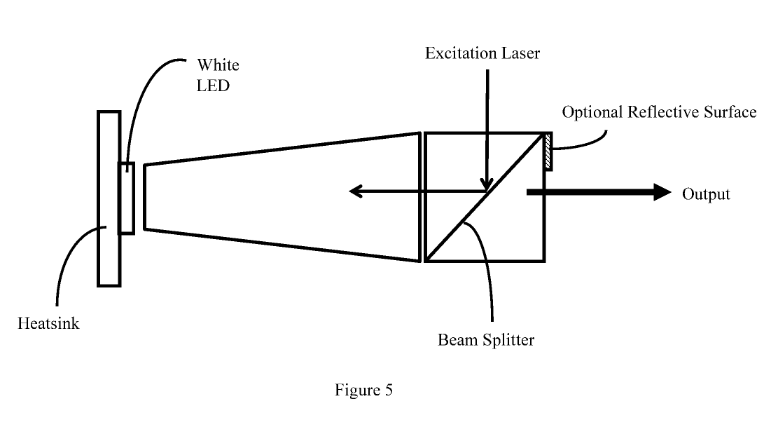

FIG. 5 shows a system using light pipes. The excitation laser light has a different wavelength than the output blue light such that a beam splitter can be used to separate the excitation laser light and the output blue light, in addition to the red and green light.

With the optional reflective surface as shown in the figure, where part of the output is reflected back into the LED, increase the brightness of the output.

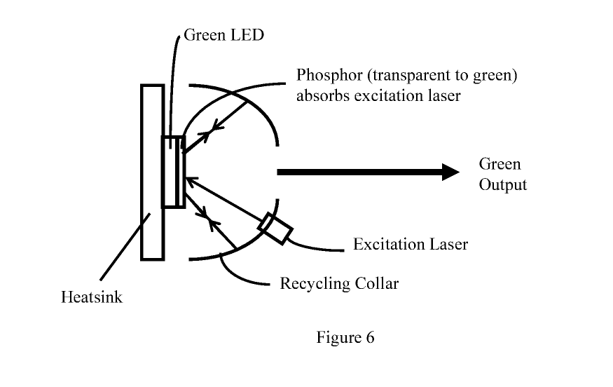

In other embodiments similar to FIG. 5 and FIG. 6, the white LED can be replaced by simple a phosphor layer coated on a heatsink.

In another embodiment, a phosphor with other color can be used producing colored light. For example, a green phosphor can be used producing green light. The laser excitation increase the green output, thus increase the brightness. In another embodiment, a red phosphor can be used.

In another embodiment as shown in FIG. 6, a phosphor of different wavelength can be used to increase the outputs of a certain color. For example, a green LED with wavelength of 540 nm is used with a green phosphor that is transparent to 540 nm, but absorbs UV and or blue, such that more green lights are generation from the excitation, thus increasing the output brightness.

Yet in another embodiment, a red phosphor can be used to increase the brightness of the red similar to the green above.

In general, any colored LED can be used and the brightness can be increased using the excitation laser directed onto the transparent phosphor as described above.

The same brightness increase using colored LED can also be implemented using the light pipe based system as shown in FIGS. 5 and 6.

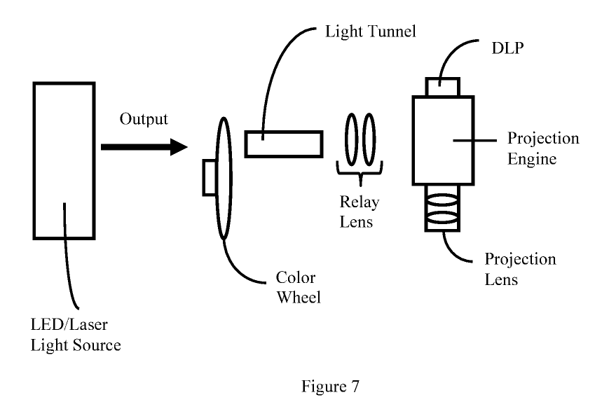

FIG. 7 shows a typical DLP projector system where this laser/LED light source can be used. The same light source can also be used on a 3LCD and LCOS projector system.

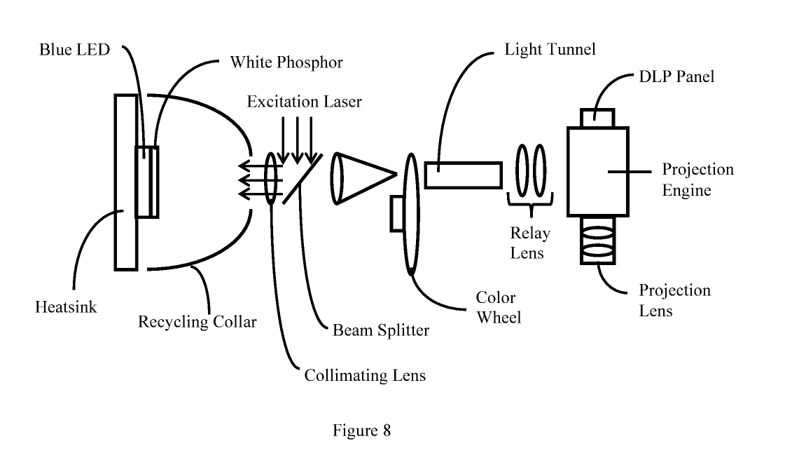

FIG. 8 shows an embodiment of a DLP projector system. The output of the light form the recycled white LED is collimated. A beam splitter is used to direct the excitation laser light onto the white LED through the collimating lens. The final output is focused into the light tunnel and eventually relayed to the DLP panel for projection.

We claim:

1. A light source for a projection display comprising:
a heat sink;
a phosphor composition provided on said heat sink, wherein said phosphor composition is a phosphor powder, a ceramic phosphor or a liquid phosphor;
one or more lasers directed at said phosphor composition;
an electronic circuit connected to said one or more lasers to regulate power output to said one or more lasers; and
a power source connected to said electronic circuit,
wherein when said one or more lasers are activated exciting said phosphor composition the light emitted from said phosphor composition is said light source for said projection display.

2. The light source for a projection display according to claim 1, further comprising a light emitting diode positioned between said heatsink and said phosphor.

3. The light source for a projection display according to claim 1, further comprising a recycling collar having a reflective interior surface, an outer surface and a light output aperture about its center, said collar affixed over said heat sink and encompassing said phosphor composition, such that light emitted from said phosphor composition that does not exit through said light output aperture of said recycling collar is redirected back at said phosphor composition.

4. The light source for a projection display according to claim 3, wherein said one or more lasers are mounted on said outer surface of said recycling collar.

5. The light source for a projection display according to claim 1, further comprising a beam splitter wherein said beam splitter controls the excitation light wavelength of the laser light that is directed at the phosphor composition and the light emitted from the phosphor composition.

6. The light source for a projection display according to claim 1, wherein said projection display is a DLP Projector system, a 3LCD projector system and a LCOS projector system.

7. The light source for a projection display according to claim 1, further comprising one or more lenses that focus the light emitted by said one or more lasers and the light emitted from said phosphor composition after excitation from said one or more lasers.

8. The light source for a projection display according to claim 1, further comprising a light pipe wherein said light pipe has an inner surface, an outer surface, a first end, a second end and an output aperture on said second end, said first end positioned over said phosphor composition and said second end having a reflective inner surface.

9. The light source for a projection display according to claim 8, wherein said inner surface of said light pipe is reflective.

10. The light source for a projection display according to claim 8, wherein said light pipe further comprises a beam splitter, wherein said beam splitter is positioned on the inner surface near said second end.
